(19) United States
(12) Patent Application Publication
(10) Pub. No.: US 2025/0357330 A1
(43) Pub. Date: Nov. 20, 2025

(54) DELTA METAL FUSE STRUCTURE

(71) Applicant: International Business Machines Corporation, Armonk, NY (US)

(72) Inventors: Nicholas Alexander POLOMOFF, Hopewell Junction, NY (US); Manasa MEDIKONDA, ALBANY, NY (US); Tao Li, Slingerlands, NY (US); Ruilong Xie, Niskayuna, NY (US); Nicolas Jean Loubet, GUILDERLAND, NY (US)

(21) Appl. No.: 18/668,950

(22) Filed: May 20, 2024

(51) Int. Cl. H01L 23/525; H01L 23/528

(52) U.S. Cl. CPC H01L 23/5256; H01L 23/5286

(57) ABSTRACT

A semiconductor device is provided that includes a d-fuse structure that includes d-fuse vias located between a backside power distribution network and a frontside back-end-of-the-line (BEOL) structure.

### BACKGROUND

The present application relates to semiconductor technology, and more particularly to a semiconductor device that includes delta metal fuse (i.e., d-fuse) vias located between a backside power distribution network and a frontside back-end-of-the-line (BEOL) structure.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Also, placing the power lines on the backside can reduce interference with signal paths and minimize heat buildup near the active device regions.

### SUMMARY

A semiconductor device is provided that includes a d-fuse structure that includes d-fuse vias located between a backside power distribution network and a frontside BEOL structure.

In one embodiment of the present application, a semiconductor device is provided that includes a d-fuse structure including a plurality of d-fuse vias located between a frontside BEOL structure including a frontside metal line and a backside power distribution network including a backside power distribution network metal line. In this embodiment, the d-fuse vias have a first portion embedded in a shallow trench isolation structure and a second portion embedded in a middle-of-the-line (MOL) dielectric layer, and the d-fuse vias are connected to the frontside metal line and the backside power distribution network metal line in a staggered pattern.

In another embodiment of the present application, a semiconductor device is provided that includes a d-fuse structure including an electrically conductive fused region located between a frontside BEOL structure including a frontside metal line and a backside power distribution network including a backside power distribution network metal line. In this embodiment, the electrically conductive fused region has a first portion embedded in a shallow trench isolation structure and a second portion embedded in a MOL dielectric layer, and the electrically conductive fused region electrically connects the frontside metal line to the backside power distribution network metal line.

### BRIEF DESCRIPTION OF THE DRAWINGS

FIG. 1 is a cross sectional view of an exemplary structure that can be employed in the present application, the exemplary structure including at least one transistor located on a semiconductor device layer of a substrate, a shallow trench isolation structure located adjacent to the semiconductor device layer, and a middle-of-the-line (MOL) dielectric layer embedding the at least one transistor and located on top of the shallow trench isolation structure.

FIG. 2 is a cross sectional view of the exemplary structure of FIG. 1 after forming frontside contact structures and a plurality of d-fuse vias in the MOL dielectric layer, wherein each d-fuse vias extends through the shallow trench isolation structure.

FIG. 3 is a cross sectional view of the exemplary structure of FIG. 2 after forming a frontside back-end-of-the-line (BEOL) structure.

FIG. 4 is a cross sectional view of the exemplary structure of FIG. 3 after bonding the frontside BEOL structure to a carrier wafer, flipping the structure and removing a semiconductor base layer of the substrate to physically expose an etch stop layer of the substrate.

FIG. 5 is a cross sectional view of the exemplary structure of FIG. 4 after removing the etch stop layer and recessing the semiconductor device layer.

FIG. 6 is a cross sectional view of the exemplary structure of FIG. 5 after forming a first backside ILD layer having backside power rails embedded therein.

FIG. 7 is a cross sectional view of the exemplary structure of FIG. 6 after forming a backside power distribution network on the first backside ILD layer.

FIG. 8 is a cross sectional view of the exemplary semiconductor device of FIG. 7 after applying energy to the exemplary semiconductor device to fuse the d-fuse vias.

FIG. 9 is a cross sectional view of an alternative semiconductor device of the present application including a protective structure surrounding the d-fuse vias.

FIG. 10 is a top down view showing a protective structure surrounding the d-fuse vias in accordance with an embodiment of the present application.

FIG. 11 is a top down view showing an alternative protective structure surrounding the d-fuse vias in accordance with another embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A delta metal fuse (or d-fuse for short), also known as a “metal fuse” or “metal link fuse,” is a type of fuse used in electronic circuits to protect against overcurrent conditions. A d-fuse includes a thin metal link that melts when the current (or other type of energy) passing through it exceeds a certain threshold, thus breaking the circuit and preventing damage to the components downstream. D-fuses are commonly used in applications where precise and reliable overcurrent protection is required, such as in power supplies, automotive electronics, and industrial equipment. The term “delta metal fuse” likely originates from the shape of the metal link within the fuse. The metal link often has a triangular or delta-like shape, resembling the Greek letter delta (Δ). This triangular shape helps concentrate the current flow at a specific point on the link, promoting uniform heating and ensuring reliable and predictable fuse operation when the current exceeds the rated threshold. So, the name “delta metal fuse” is derived from the shape of the metal link rather than any specific electrical or functional characteristic. In the present application, the d-fuse includes d-fuse vias that have a delta-like shape.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure Includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described and illustrated in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside interconnect structure. The backside interconnect structure can be a backside power distribution network that is capable of delivering power to the transistor through the backside of the semiconductor device.

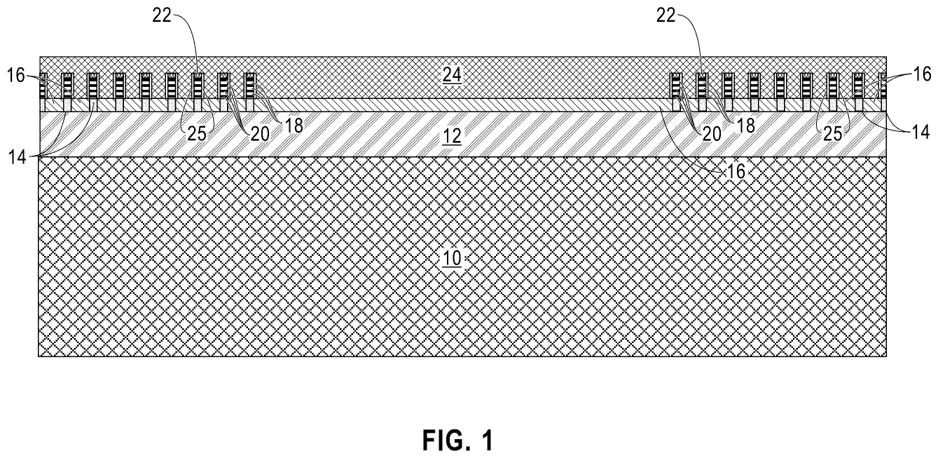

Referring first to FIG. 1, there is illustrated an exemplary structure that can be employed in the present application. Notably, the exemplary structure illustrated in FIG. 1 includes at least one transistor located on a semiconductor device layer 14 of a substrate, a shallow trench isolation structure 16 located adjacent to semiconductor device layer 14, and a MOL dielectric layer 24 embedding the at least one transistor and present on top of the shallow trench isolation structure 16. The at least one transistor can be a nanosheet transistor which includes a vertical stack of spaced apart semiconductor channel material nanosheets 18 and a gate structure 20 that wraps around a portion of each semiconductor channel material nanosheet 18. The exemplary structure illustrated in FIG. 1 illustrates a plurality of first nanosheet transistors located on a first region of the substrate (e.g., see the left hand side of FIG. 1) and a plurality of a plurality of second nanosheet transistors located on a second region of the substrate (e.g., see the left hand side of FIG. 1). The transistors are located in an active device region of the substrate. The region between the first and second regions is a non-active device region that includes the shallow trench isolation structure 16, and will subsequently include a portion of d-fuse vias present therein. The plurality of first nanosheet transistors can be of a same, or a different, conductivity-type as the plurality of second nanosheet transistors. For example, the plurality of first nanosheet transistors can be NFETs, while the plurality of second nanosheet transistors can be PFETs, or alternatively, the plurality of first nanosheet transistors can be PFETs, while the plurality of second nanosheet transistors can be NFETs.

In addition to the semiconductor device layer 14, the substrate can also include a semiconductor base layer 10 and/or an etch stop layer 12. Embodiments are contemplated in which the semiconductor base layer 10 and/or the etch stop layer 12 are omitted and the substrate includes only the semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Shallow trench isolation structure 16 is located in an upper portion of the substrate and is located between the first and second plurality of nanosheet transistor. In some embodiments, and as is illustrated, shallow trench isolation structures 16 can also be present between each of the transistors within a specific device region. The shallow trench isolation structures that are located between each of the transistors within a specific device region are optional. Each shallow trench isolation structure 16 is present in the semiconductor device layer 14 of the substrate. Each shallow trench isolation structure 16 can include a trench dielectric liner and a trench dielectric material. In some embodiments, the trench dielectric liner can be omitted. In one example, the trench dielectric liner is composed of silicon nitride, and the trench dielectric material is composed of silicon dioxide. When present, the trench dielectric liner is present along a sidewall and a bottom wall of the trench dielectric material. In some embodiments, each shallow trench isolation structure 16 can have a topmost surface that is substantially coplanar with a topmost surface of the substrate (e.g., the semiconductor device layer 14). In other embodiments, each shallow trench isolation structure 16 can have a topmost surface that is vertically offset (i.e., higher or lower) than a topmost surface of the substrate (e.g., the semiconductor device layer 14).

Each semiconductor channel material nanosheet 18 that is present in the vertical stack of spaced apart semiconductor channel material nanosheets 18 is composed of a fourth semiconductor material. The fourth semiconductor material can be compositionally the same, or compositionally different from the second semiconductor material that provides the semiconductor device layer 14. In some embodiments, the fourth semiconductor material that provides each semiconductor channel material nanosheet 18 provides high channel mobility for NFET devices. In other embodiments, the fourth semiconductor material that provides each semiconductor channel material nanosheet 18 provides high channel mobility for PFET devices. In one example, each semiconductor channel material nanosheet 18 is composed of silicon.

The gate structure 20 includes a gate dielectric material and a gate electrode, both of which are not separately shown, but intended to be within the region defined by the gate structure. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. All dielectric constants mentioned herein are relative to a vacuum unless otherwise noted. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOxNy), tantalum oxide (TaOx), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The first gate dielectric material can further include dopants such as lanthanum (La), aluminum (Al) and/or magnesium (Mg). The first gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

Although not illustrated in the cross sectional view of FIG. 1, each nanosheet transistor would also include a source/drain region located on each side of the vertical stack of spaced apart semiconductor channel material nanosheets 18. In the present application, the source/drain regions would be behind, and in front of, the plane of the drawing sheet including the exemplary structure illustrated in FIG. 1. The source/drain regions extend outward from a sidewall of each semiconductor channel material nanosheet 18. Each source/drain region is composed of a fifth semiconductor material and a dopant. As used herein, a “source/drain” region can be a source region or a drain region depending on subsequent wiring and application of voltages during operation of the transistor. The fifth semiconductor material that provides the source/drain regions can be compositionally the same as, or compositionally different from, the fourth semiconductor material that provides each semiconductor channel material nanosheet 18. The dopant that is present in the source/drain regions can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions can have a dopant concentration of from 4×10²⁰ atoms/cm³ to 3×10²¹ atoms/cm³.

Although not illustrated in the cross sectional view of FIG. 1, each nanosheet transistor can also include inner spacers which are positioned between end portions of each of the semiconductor channel material nanosheets 18. The inner spacers are composed of a dielectric spacer material such as, for example, silicon dioxide, SiN, SiBCN, SiOCN or SiOC.

As is illustrated in FIG. 1, a dielectric cap 22 is present atop each nanosheet transistor. The dielectric cap 22 can include a dielectric hard mask material such as, for example, silicon dioxide, silicon nitride and/or silicon oxynitride. Gate dielectric spacer 25 can also be present along the sidewalls of each nanosheet transistor. The gate dielectric spacer 25 is composed of one of the dielectric spacers mentioned above.

The shallow trench isolation structures 16, the nanosheet transistors and the dielectric cap 22 can be formed utilizing well known front-end-of-the-line (FEOL) processing steps. The FEOL processing steps can include various deposition and patterning steps. The nanosheet transistors can be formed utilizing well known nanosheet transistor formation processes.

The MOL dielectric layer 24 is composed of dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The MOL dielectric layer 24 can be formed by a deposition process such as, for example, chemical vapor deposition (CVD), plasma enhanced chemical vapor deposition (PECVD) or spin-on coating. A planarization process such as, for example, chemical mechanical polishing (CMP) can follow the deposition process.

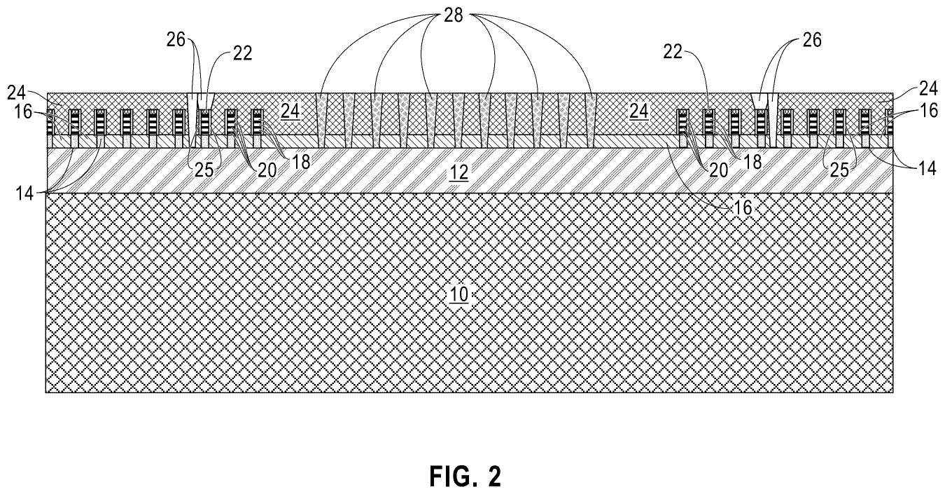

Referring now to FIG. 2, there is illustrated the exemplary structure of FIG. 1 after forming frontside contact structures 26 and a plurality of d-fuse vias 28 in the MOL dielectric layer 24, wherein each d-fuse via 28 extends through the shallow trench isolation structure 16 and is present in the MOL dielectric layer 24. The plurality of d-fuse vias 28 provide a component of a d-fuse structure in accordance with the present application. The frontside contact structures 26 and the plurality of d-fuse vias 28 can be formed in any order. That is, the frontside contact structures 26 can be formed before, or after the plurality of d-fuse vias 28. The frontside contact structures 26 can include frontside gate contact structures, frontside source/drain contact structures or any combination thereof. Each frontside contact structure 26 is composed of at least a contact conductor material. The contact conductor material can include, for example, a silicide liner, such as Ni, Pt, NiPt, an adhesion frontside metal liner, such as TiN, and conductive metals such as W, Cu, Al, Co, Ru, Mo, Os, Ir, Rh, or an alloy thereof. Each frontside contact structure 26 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. Each frontside contact structure 26 can be formed by a metallization process. A metallization process can include forming openings in a material layer by lithography and etching, and then filling each of the openings with a desired material. The filling can include a deposition process, followed by a planarization process.

The d-fuse vias 28, which can be formed utilizing a metallization process, are composed of an electrically conductive metal or an electrically conductive metal alloy. Illustrative examples of electrically conductive metals that can be used include, but are not limited to, Cu, Al, Co, Ru, Mo, Os, Ir, or Rh. An illustrative electrically conductive alloy that can be used includes, but is not limited to, a Cu—Al alloy. In the present application, each d-fuse via 28 has sidewalls that tapers inward from the top to the bottom such that each d-fuse via 28 has an upper portion (i.e., second portion) whose width is greater than a lower portion (i.e., first portion). This provides a delta shape to each of the d-fuse vias 28. The lower portion of each d-fuse via 28 is typically present in the shallow trench isolation structure 16, while the upper portion is typically present in the MOL dielectric layer 24. In the non-active area that includes the d-fuse vias 28, the pitch between each neighboring d-fuse vias 28 is from 10 micrometers (i.e., μm) or less, with a pitch from 1 μm or less, being more typical. Throughout the present application, the term “pitch” is a measurement between one point of a structure to the exact point of the neighboring structure. In some embodiments of the present application, each d-fuse via 28 is typically spaced apart and separated from each other by both the MOL dielectric layer 24 and the shallow trench isolation structure 16. The d-fuse vias 28 are designed to be sufficiently close enough to one another so as to allow the d-fuse vias 28 to fuse together when a sufficient energy (electrical, heat, etc.) is applied thereto.

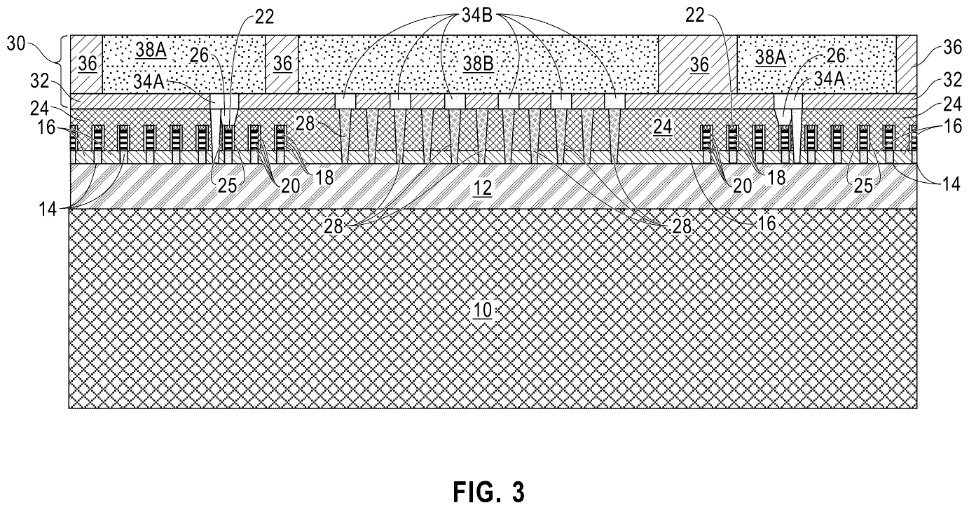

Referring now to FIG. 3, there is illustrated the exemplary structure of FIG. 2 after forming a frontside BEOL structure 30. The frontside BEOL structure 30 includes a first metal level that includes frontside metal vias 34A, 34B embedded in a first frontside interlayer dielectric (ILD) layer 32, and a second metal level that includes frontside metal lines 38A, 38B embedded in second frontside ILD layer 36. The frontside BEOL structure 30 can also include additional metal levels located beneath and/or above the second metal level which include other frontside BEOL wiring embedded in other frontside ILD layers.

The first frontside ILD layer 32 and the second frontside ILD layer 36 (and the other frontside ILD layers) are composed of a dielectric material as defined above for the MOL dielectric layer 24. The dielectric material that provides the first frontside ILD layer 32 can be compositionally the same as, or compositionally different from, the dielectric material that provides the second frontside ILD layer 36. The frontside metal vias 34A, 34B and the frontside metal lines 38A, 38B (and other frontside BEOL wiring) are composed of an electrically conductive metal or an electrically metal alloy, both as defined above. A diffusion barrier liner can be present along the sidewall and a bottom wall of the frontside metal vias 34A, 34B, the frontside metal lines 38A, 38B and other frontside BEOL wiring. The frontside metal vias 34A, 34B and the frontside metal lines 38A, 38B are typically, but not necessary always composed of a same electrically conductive metal or electrically conductive metal alloy.

In the present application, the frontside metal vias 34A are used in connecting the nanosheet transistors (via the frontside contact structures 26) to frontside metal line 38A. In the present application, the frontside metal vias 34B are used to connect alternating d-fuse vias 28 (i.e., every other d-fuse via 28) to frontside metal line 38B as shown in FIG. 3; d-fuse vias 28 not in contact with the frontside metal vias 34B are not connected to the frontside metal line 38B. In the present application, the frontside metal vias 34B land on MOL dielectric layer 24. The frontside metal line 38B can serve as a frontside electrode of the d-fuse structure of the present application.

The frontside BEOL structure 30 can be formed utilizing any well-known BEOL process. For example, the BEOL structure 30 can be formed by a damascene process and/or a substrative etch process in which the electrically conductive material is first deposited and then patterned, and thereafter the frontside ILD layer is formed by deposition, followed by a planarization process.

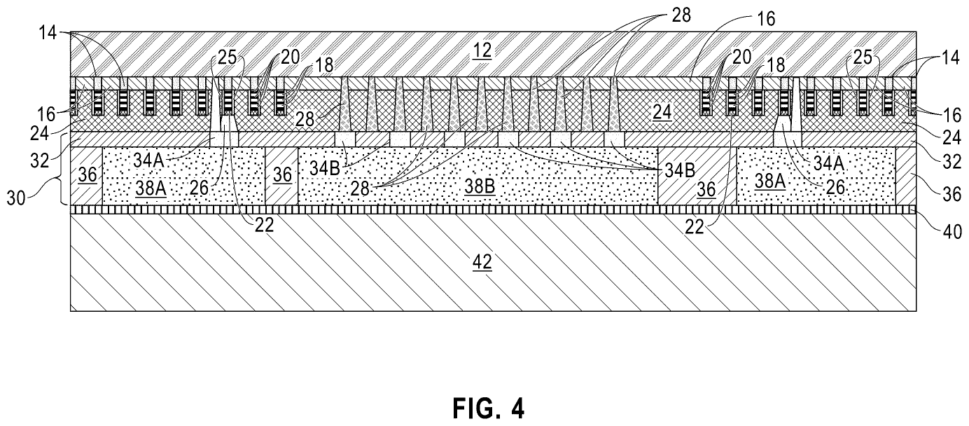

Referring now to FIG. 4, there is illustrated the exemplary structure of FIG. 3 after bonding the frontside BEOL structure 30 to a carrier wafer 42, flipping the structure and removing the semiconductor base layer 10 of the substrate to physically expose the etch stop layer 12 of the substrate. The carrier wafer 42 includes a semiconductor material as mentioned above. The bonding includes the use of a bonding dielectric layer 40 that is applied (via a deposition process) to either the frontside BEOL structure 30 or the carrier wafer 42, or to both the frontside BEOL structure 30 and the carrier wafer 42 prior to bonding. The bonding dielectric layer 40 can be composed of a bonding dielectric material such as, for example, TEOS (tetraethyl ortho silicate), SiO₂, SiCN, and/or SiCOH. Bonding includes any well-known bonding process in which a wafer is bonded to another wafer or structure.

After bonding the carrier wafer 42 to the frontside BEOL structure 30, the structure is flipped 180° such backside of the structure is physically exposed. Typically, and in the illustrated embodiment, the flipping step physically exposed the semiconductor base layer 10 of the substrate. If the semiconductor base layer 10 is not present, the flipping can either physically expose the etch stop layer 12 (if the same is present) or the semiconductor device layer 14 (if the etch stop layer 12 is not present). The semiconductor base layer 10 can be removed utilizing a material removal process that is selective in removing the semiconductor base layer 10.

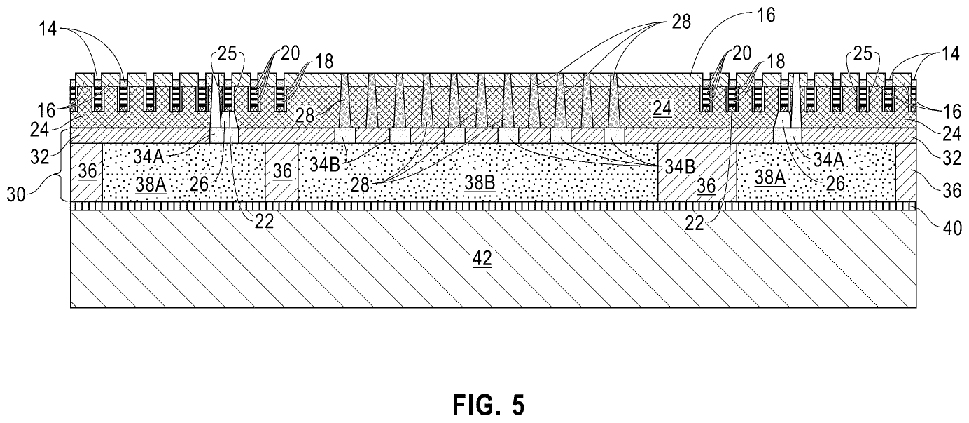

Referring now to FIG. 5, there is illustrated the exemplary structure of FIG. 4 after removing the etch stop layer 12 and recessing the semiconductor device layer 14. The etch stop layer 12 can be removed utilizing a material removal process that is selective in removing the etch stop layer 12. The removal of the etch stop layer 12 can be omitted when no etch stop layer 12 is present. The removal of the etch stop layer 12 can physically expose each of the d-fuse vias 28. The recessing of the semiconductor device layer 14 is performed utilizing a recess etching process. The recessing step thins the semiconductor device layer 14 such that the remaining semiconductor device layer 14 has a thickness that is less than the shallow trench isolation structures 16. The recessing step thus physically exposes each shallow trench isolation structure 16 and as shown in FIG. 5.

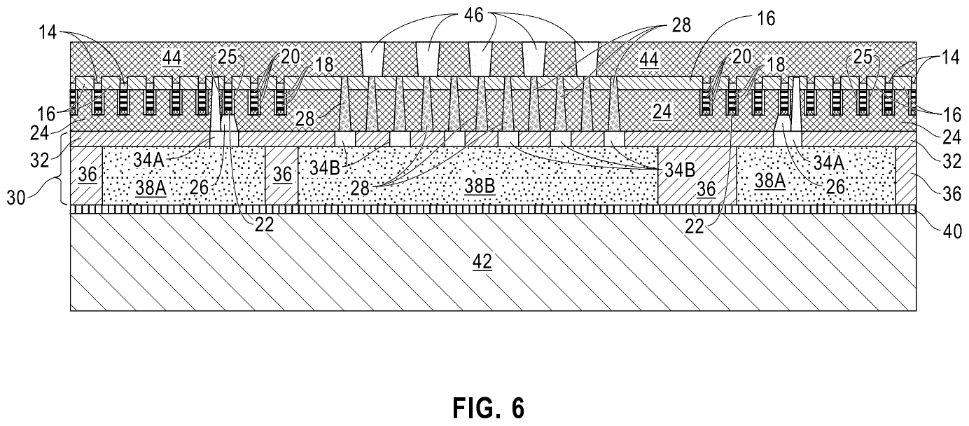

Referring now to FIG. 6, there is illustrated the exemplary structure of FIG. 5 after forming a first backside ILD layer 44 having backside power rails 46 embedded therein. The first backside ILD layer 44 is composed of a dielectric material as mentioned above for the MOL dielectric layer 24. The first backside ILD layer 44 can be formed by deposition, followed by a planarization process. Each backside power rail 46 is composed of an electrically conductive power rail material. The electrically conductive power rail material includes, but is not limited to, W, Co, Ru, Al, Cu, Pt, Rh, or Pd. A thin metal adhesion layer, such as TiN, TaN, etc. can be also formed along the sidewall and bottom wall of each backside power rail 46. In some embodiments, the backside power rails 46 are formed by a damascene process. In other embodiments, the backside power rails 46 are formed by a substrative etching process as described above.

In the present application, the backside power rails 46 are in contact with alternating d-fuse vias 28 that are not in contact with the frontside metal vias 34B. The backside power rails 46 will provide connection of these alternating d-fuse vias 28 to a backside power distribution network metal line 52 to be subsequently formed. The backside power distribution network metal line 52 will serve as a second electrode of the d-fuse structure of the present application. Each backside power rail 46 lands on a surface of the shallow trench dielectric structure 16. In the present application, the d-fuse vias 28 are connected to the frontside metal line 38B and the backside power distribution network metal line 52 in a staggered pattern. For example, every odd numbered d-fuse via 28 is connected to the frontside metal line 38B and every even numbered d-fuse via 28 is connected to the backside power distribution network metal line 52.

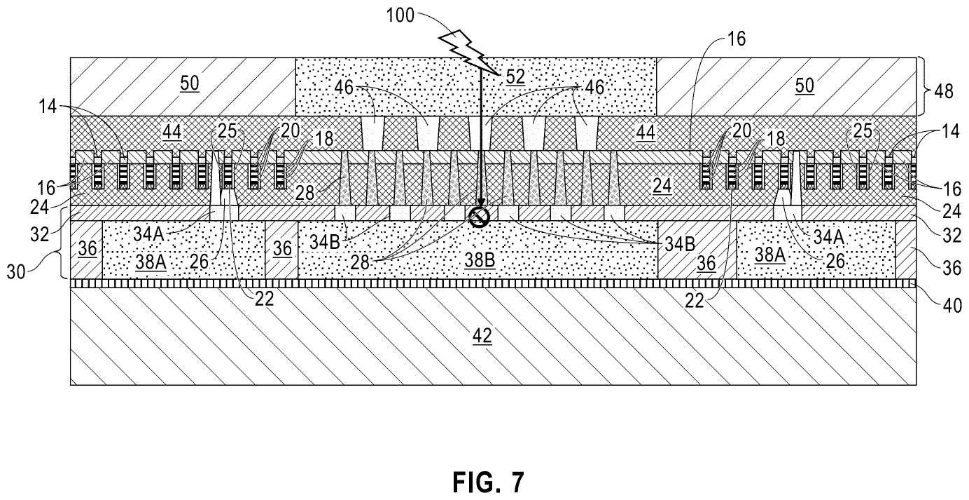

Referring now to FIG. 7, there is illustrated the exemplary structure of FIG. 6 after forming a backside power distribution network 48 on the first backside ILD layer 44. The backside power distribution network 48 includes a backside power distribution network metal line 52 embedded in a second backside ILD layer 50. The second backside ILD layer 50 is composed of a dielectric material as mentioned above for the MOL dielectric layer 24. The dielectric material that provides the second backside ILD layer 50 can be compositionally the same as, of compositionally different from, the dielectric material that provides the first backside ILD layer 44. The second backside ILD layer 50 can be formed by deposition, followed by a planarization process. The backside power distribution network metal line 52 can be composed of an electrically conductive metal or electrically conductive metal ally as mentioned previously herein. The backside power distribution network metal line 52 can be formed by a damascene process or, alternatively, a subtractive etching process can be used in forming the backside power distribution network metal line 52. Although not illustrated, the backside power distribution network 48 can include additional backside power distribution network levels below and/or on top of the backside power distribution network level that includes the backside power distribution network metal line 52 embedded in a second backside ILD layer 50. As is shown, the backside power distribution network metal line 52 is in contact with each of the backside power rails 46.

Notably, FIG. 7 illustrates a semiconductor device in accordance with the present application. The semiconductor device is at an initial stage in which the d-fuse vias 28 are not fused together. The semiconductor device includes a d-fuse structure that includes d-fuse vias 28 located between backside power distribution network 48 and frontside BEOL structure 30. The backside power distribution network 48 includes backside power distribution network metal line 52, and the frontside BEOL structure 30 includes frontside metal line 38B. In the illustrated embodiment of FIG. 7, the d-fuse structure includes a plurality of d-fuse vias 28 having a first portion embedded in shallow trench isolation structure 16 and a second portion embedded in MOL dielectric layer 24. In the d-fuse structure illustrated in FIG. 7, the d-fuse vias 28 are connected to frontside metal line 38B and backside power distribution network metal line 52 in a staggered pattern. In this initial stage (i.e., “off-state”), energy (electrical, heat, etc.) 100 is applied to the semiconductor device and electrical current travels in the direction of the arrow illustrated in FIG. 7. Note that the energy 100 is insufficient to melt and fuse the d-fuse vias 28 hence the electrical current does not pass through the backside of the semiconductor device.

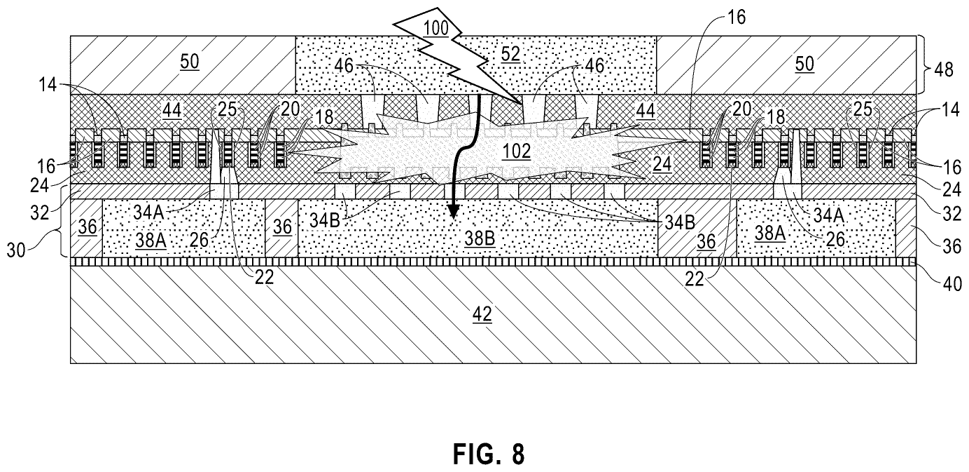

Referring now to FIG. 8, there is illustrated the exemplary semiconductor device of FIG. 7 after applying energy 100 to the exemplary semiconductor device to fuse the d-fuse vias 28; in FIG. 8 an electrically conductive fused region 102 is shown in which the d-fuse vias 28 are fused together such that an electrical connection is established between the frontside metal line 38B and backside power distribution network metal line 38B. The energy 100 can be electrical energy, heat or any other type of energy that can first metal the d-fuse vias 28 and cause fusion of the melted metal (or metal alloy) that provides the d-fuse vias 28. The electrically conductive fused region 102 is a unified structure that can conduct an electrical signal. In some embodiments, the electrically conductive fused region 102 can be composed of an amorphous metal or metal alloy. While the present application illustrates the fusing of all the d-fuse vias 28, it is possible to have some of the d-fuse vias 28 to fuse together, while having other d-fuse vias 28 not fused together. In this embodiment (i.e., “on-state”), the energy 100 melts and fuses the d-fuse vias 28 allowing electrical current to travel from the backside of the semiconductor device to the frontside side of the semiconductor device in the direction of the arrow shown in FIG. 8. Note that the electrical path is a meandering (i.e., serpentine) path because of the staggered wiring configuration of the original d-fuse structure. Upon fusion and formation of the electrically conductive fused region 102, redundant or auxiliary devices, macros, etc. built with respect to the frontside BEOL structure 30 can be accessed.

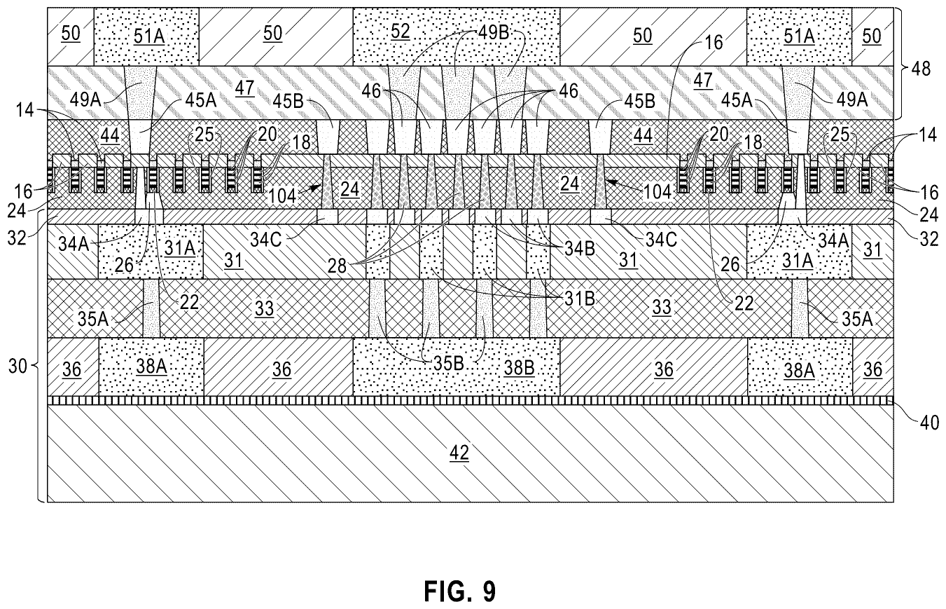

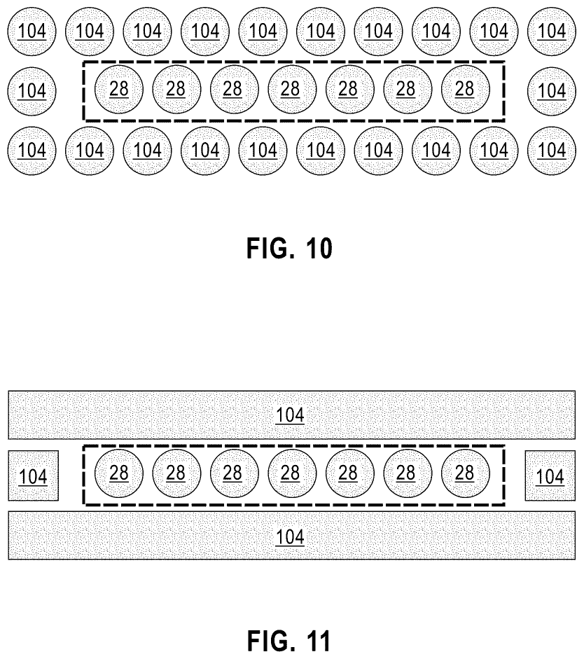

Referring now to FIG. 9 and FIG. 10, there is illustrated an alternative semiconductor device of the present application including a protective structure 104 surrounding the d-fuse vias 28. In this embodiment, the protective structure 104 is in the form of a metal via that is composed of an electrically conductive metal or electrically conductive metal alloy as defined above. In this embodiment, the protective structure 104 is embedded in the MOL dielectric layer 24 and is sufficiently spaced apart from the d-fuse vias 28 such that upon application of energy the protective structure 104 does not fuse with any of the d-fuse vias. In this embodiment, the backside power distribution network further includes a lower level positioned between the first backside ILD layer 44 and the upper level including the backside power distribution network metal line 52 embedded in the second backside ILD layer 50. The second backside ILD layer 50 also includes backside metal line 51A embedded therein. In this embodiment, the lower level includes backside metal vias 49A, 49B embedded in a third backside ILD layer 47. In this embodiment, the first backside ILD layer 44 also includes backside metal structures 45A, 45B embedded therein.

In this embodiment, the nanosheet transistor is electrically connected to the backside metal line 51A by a vertical stack of a backside metal via 49A and a backside metal structure 45A. In this embodiment, alternating d-fuse vias 28 are connected to the backside power distribution network metal line 52 by a vertical stack of a backside power rail 46 and a backside metal via 49B.

In the embodiment, the frontside BEOL structure includes an upper BEOL level including BEOL metal structures 31A, 31B embedded in a first BEOL dielectric layer 31, and a mid-BEOL level including BEOL metal vias 35A, 35B embedded in a second BEOL dielectric layer 33 that is positioned between the first frontside ILD layer 32, and the lower level that includes frontside metal lines 38A, 38B embedded in second frontside ILD layer 36. In this embodiment, the first frontside ILD layer 32 also includes frontside metal via 34C in contact with the protective structure 104.

In this embodiment, the nanosheet transistor is electrically connected to the frontside metal lines 38A by a vertical stack of a frontside metal via 34A, a BEOL metal structure 31A and a BEOL metal via 35A. In this embodiment, alternating d-fuse vias 28 are connected to the frontside metal line 38B by a vertical stack of a BEOL metal structure 31B and a BEOL metal via 35A. In this embodiment, the protective structure 104 is positioned between a BEOL metal via 35A and a backside metal structure 45B.

The d-fuse structure illustrated in FIG. 9 works the same as the d-fuse structure illustrated in FIG. 7 thus upon sufficient energy the d-fuse vias 28 can fuse together and provide a fuse region that is electrically conductive such that the frontside and the backside of the device are electrically connected.

Referring now to FIG. 11, there is illustrated an alternative protective structure 104 surrounding the d-fuse vias 28 in accordance with another embodiment of the present application. In this embodiment, the alternative protective structure 104 is in the shape of a bar. It is noted that the protective structure 104 of FIGS. 9, 10 and 11 can implemented into the exemplary structure shown in FIGS. 7 and 8.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a d-fuse structure comprising a plurality of d-fuse vias located between a frontside back-end-of-the-line (BEOL) structure comprising a frontside metal line and a backside power distribution network comprising a backside power distribution network metal line, wherein the d-fuse vias have a first portion embedded in a shallow trench isolation structure and a second portion embedded in a middle-of-the-line (MOL) dielectric layer, and the d-fuse vias are connected to the frontside metal line and the backside power distribution network metal line in a staggered pattern.

2. The semiconductor device of claim 1, wherein the plurality of d-fuse vias is surrounded by a protective structure.

3. The semiconductor device of claim 2, wherein the protective structure has a shape of a via or a bar.

4. The semiconductor device of claim 1, wherein each d-fuse via of the plurality of d-fuse vias is composed of an electrically conductive metal or electrically conductive metal alloy.

5. The semiconductor device of claim 1, wherein a pitch between each neighboring d-fuse via of the plurality of d-fuse vias is from 10 μm or less.

6. The semiconductor device of claim 1, wherein each d-fuse via of the plurality of d-fuse vias is spaced apart and separated from each other by both the MOL dielectric layer and the shallow trench isolation structure.

7. The semiconductor device of claim 1, wherein the frontside metal line is connected to alternating d-fuse vias of the plurality of d-fuse vias by frontside metal vias.

8. The semiconductor device of claim 7, wherein the frontside metal vias are embedded in a frontside interlayer dielectric (ILD) and each frontside metal via lands on the MOL dielectric layer.

9. The semiconductor device of claim 1, wherein the backside power distribution network metal line is connected to alternating d-fuse vias of the plurality of d-fuse vias by backside power rails.

10. The semiconductor device of claim 9, wherein the backside power rails are embedded in a backside ILD layer, and each backside power rail lands on a surface of the shallow trench dielectric structure.

11. The semiconductor device of claim 1, further comprising at least one transistor located adjacent to the d-fuse structure, wherein the at least one transistor is electrically connected to another frontside metal line of the BEOL structure.

12. A semiconductor device comprising:
a d-fuse structure comprising an electrically conductive fused region located between a frontside BEOL structure including a frontside metal line and a backside power distribution network including a backside power distribution network metal line, wherein the electrically conductive fused region has a first portion embedded in a shallow trench isolation structure and a second portion embedded in a middle-of-the-line (MOL) dielectric layer, and the and the electrically conductive fused region electrically connects the frontside metal line to the backside power distribution network metal line.

13. The semiconductor device of claim 12, wherein the electrically conductive fused region is surrounded by a protective structure.

14. The semiconductor device of claim 13, wherein the protective structure has a shape of a via or a bar.

15. The semiconductor device of claim 12 wherein the frontside metal line is electrically connected to electrically conductive fused region by frontside metal vias.

16. The semiconductor device of claim 15, wherein the frontside metal vias are embedded in a frontside interlayer dielectric (ILD) and each frontside metal via lands on the MOL dielectric layer.

17. The semiconductor device of claim 12, wherein the backside power distribution network metal line is electrically connected to the electrically conductive fused region by backside power rails.

18. The semiconductor device of claim 17, wherein the backside power rails are embedded in a backside ILD layer, and each backside power rail lands on a surface of the shallow trench dielectric structure.

19. The semiconductor device of claim 12, further comprising at least one transistor located adjacent to the d-fuse structure, wherein the at least one transistor is electrically connected to another frontside metal line of the BEOL structure.
